(19) United States
(12) Patent Application Publication
(10) Pub. No.: US 2003/0001250 A1
(43) Pub. Date: Jan. 2, 2003

(54) TCP optical device

(75) Inventors: Lai Chien-Hung, Kaohsiung (TW); Lin Hsin-Cheng, Kaohsiung (TW); Peng Bing-Yen, Kaohsiung (TW)

Correspondence Address: DOUGHERTY & TROXELL, SUITE 1404, 5205 LEESBURG PIKE, FALLS CHURCH, VA, 22041, US

(73) Assignee: Walsin Advanced Electronics LTD

(21) Appl. No.: 09/888,379

(22) Filed: Jun. 27, 2001

(51) Int. Cl. H01L 23/06

(52) U.S. Cl. 257/684

(57) ABSTRACT

An optical device with a tape carrier package is provided for low cost packaging and better stability. The optical device comprises: an optical sensor chip having a plurality of electrodes on its sensible surface; a flexible circuit board having an upside surface, an underside surface and a window; a plurality of metal circuits formed on the flexible circuit board and each of them having an inner lead extending into the window for bonding with the corresponding electrode; a base having a recession which is corresponding to the window and located under the underside surface of the flexible circuit board, and having a surrounding dam which extends onto the upside surface of the flexible circuit boars; and a transparent cover fixed attached to the surrounding dam for sealing the optical sensor chip.

### FIELD OF THE INVENTION

The present invention is relating to an optical device with a tape, particularly to an optical device in a tape carrier package type with inner lead bonding.

### BACKGROUND OF THE INVENTION

It is familiar that the optical device includes a properly protected optical sensor chip, generally the optical sensor chip being installed in a ceramic board with a recession, furthermore being sealed by a transparent glass cover, however the space for sealing the optical sensor chip generally being vacuum or filling with inert gas so as to prevent seeping vapor, thus this ceramic-packaging costis high.

In order to decrease the packaging cost for optical device, a CCD package of image sensor element is disclosed in U.S. Pat. No. 6,011,294 “low cost CCD packaging”. As shown in FIGS. 6 and 7, The CCD package 10 includes a plastic base 12, a plastic ring frame 14 and a glass cover 16 to form a hermetic space. The glass cover 16 is used to seal the optical sensor chip 11 being on the topside surface 24 of plastic ring frame 14. A flexible circuit 18 located between plastic base 12 and plastic frame 14 has the conductive leads 19 which are on the substrate 20. The optical sensor chip 11 is adhered onto the upside surface of flexible circuit 18 and electrically interconnects with the flexible circuit 18 by the bonding wires 29. However, there is a defect that the optical sensor chip 11 is directly adhered to the flexible circuit 18 without a fixed base, therefore the stability is worse resulting in level precision deviating and horizontal displacement of optical sensor chip 11, seriously influencing the angle and position of optical sensation. Moreover, if flexible circuit 18 is wider than plastic base 12 for width, the flexible circuit 18 is adhered to plastic base 12 and plastic frame 14 by its underside surface and its upside surface respectively, resulting in a worse sealing.

### SUMMARY

The first object of the present invention is to provide an optical device with a tape, comprising a molded base to carry optical sensor chip and fix the flexible circuit board, the optical sensor chip then being stably fixed on the base to achieve lower cost packaging and better stability for an optical device.

The second object of the present invention is to provide an optical device with a tape, comprising a flexible circuit board which has metal circuits. The inner leads of metal circuits are connected with optical sensor chip by thermal compression and all outer leads of metal circuits are extended to same side, so that it is not necessary to surface-mounting to printed circuit board for quick assembling and wide adjustable range for an optical device.

The third object of the present invention is to provide a TCP packaging method for an optical device, by means of thermal compression to eletrically connect flexible circuit board with optical sensor chip, and then molding the base for carrying optical sensor chip, an optical device with low cost packaging and better stability is achieved.

The optical device with a tape carrier packaging according to the present invention comprises:

an optical sensor chip having a plurality of electrodes on its sensible surface;

a flexible circuit board having an upside surface, an underside surface and a window wherein the underside surface around the window is adhered to the perimeter of the sensible surface of the optical sensor chip;

a plurality of metal circuits formed on the flexible circuit board, their inner leads extending to the window for bonding with the corresponding electrodes of optical sensor chip;

a base having a recession and a surrounding dam, wherein the recession located under the underside surface of the flexible circuit board accommodates optical sensor chip and is corresponding to the window, the surrounding dam extends onto the upside surface of flexible circuit board; and

a transparent cover connecting with the surrounding dam for sealing the optical sensor chip.

### DESCRIPTION OF THE DRAWINGS

FIG. 1 is a sectional view of an optical device with a tape carrier package according to the first embodiment of the present invention.

FIG. 2 is a top view of the optical sensor chip connected with the tape of flexible circuit board according to the first embodiment.

FIG. 3 is a perspective view of folding portable telephone using the optical device with a tape carrier package according to the first embodiment.

FIG. 4 is a sectional view of an optical device with a tape carrier package according to the second embodiment of the present invention.

FIG. 5 is a sectional view of an optical device with a tape carrier package according to the third embodiment of the present invention.

FIG. 6 is a sectional side view of a CCD package disclosed in U.S. Pat. No. 6,011,294 “low cost CCD packaging”.

FIG. 7 is a top view of a CCD package disclosed in U.S. Pat. No. 6,011,294 “low cost CCD packaging”.

### DETAILED DESCRIPTION OF THE PRESENT INVENTION

Referring to the drawings attached, the present invention will be described by means of the embodiments below.

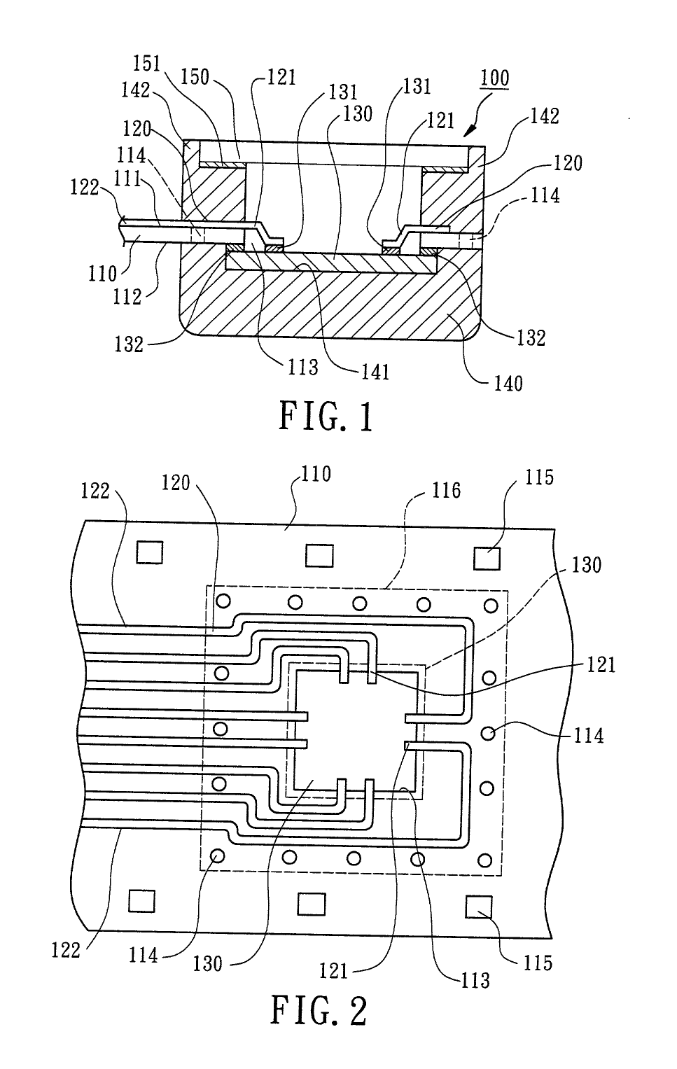

According to the optical device with a tape carrier package for the present invention, in the first embodiment, FIG. 1 is a sectional view of the optical device 100 with a tape carrier package and FIG. 2 is a top view of the optical device 100 with a tape carrier package prior to molding.

The optical device 100 with a tape carrier package mainly comprises a flexible circuit board 110, an optical sensor chip 130, a base 140 and a transparent cover 150, wherein the optical sensor chip 130 is a charge coupled device, photodiode, infrared sensor element or image sensor element, having a sensible surface used to sense, and forming a plurality of gold bumps 131 on the sensible surface for being the electrodes of optical sensor chip 130 and are used to bond with the inner leads 121 of metal circuits 120 on the flexible circuit board 110.

The flexible circuit board 110 is made from a tape with a polyimide flexible material, can be rolled in a reel. The flexible circuit board 110 has a single-layer or multi-layers structure, in this embodiment illustrating is a single-layer circuit board. The flexible circuit board 110 has an upside surface 111, an underside surface 112 and a window 113 corresponding to the optical sensor chip 130, in this embodiment for size the window 113 is a little smaller than optical sensor chip 130. A plurality of copper metal circuits 120 are formed on the upside surface 111, each metal circuit 120 has an inner lead 121 and an outer lead 122, the inner lead 121 extending to the window 113 mentioned above and being bonded with the corresponding electrode 131 of optical sensor chip 130 by thermal compression, the outer leads 122 of metal circuits 120 extending to a same direction and connecting to an electrical plug. Besides, the flexible circuit board 110 further forms a plurality of openings 114 around the window 113 used to enable the thermosetting plastic filler to flow and fixed holes 115 with regular interval at the two sides of tape of flexible circuit board 110 for transmission, and there is at least a defined molding area 116 (as shown in FIG. 2) to be an area for molding the base 140. Moreover, there is adhesive compound 132 like thermal melting compound formed on the underside surface 112 of flexible circuit board 110 around the window 113 so as to adhere the perimeter of upside surface of optical sensor chip 130.

The base 140 is formed by the technique of molding and injection filling the foregoing molding area 116 with thermosetting plastic. The base 140 has a recession 141 used to accommodate optical sensor chip 130 and located under the underside surface 112 of flexible circuit board 110 corresponding to the window 113, and a surrounding dam 142 extending onto the upside surface 111 of flexible circuit board 110 and fixedly attaching a transparent cover 150 of glass material by the methods of adhering, thermal sealing, ultrasonic or laser bonding etc. In this embodiment, the transparent cover 150 is adhered by adhesive compound 151 of thermal melting compound to the recession formed at the upside of the surrounding dam 142, using transparent cover 150 and base 140 to seal the optical sensor chip 130, generally filling the hermetic space between transparent cover 150 and base 140 with inert gas of low humidity like nitrogen or argon, or becoming vacuum.

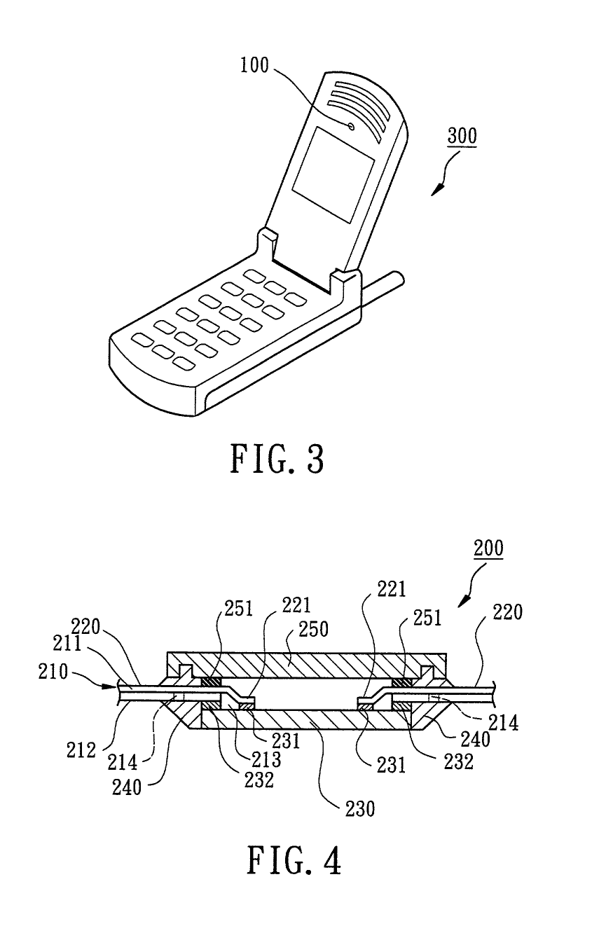

The optical sensor chip 130 is carried and fixed by the hard base 140 so that has a better stability in hermetic space after packaging. Therefore, the optical device with a tape carrier package has not only lower cost packaging (replacing of ceramic board) but also better quality, uneasy for level precision deviating and horizontal displacement. Meantime, the outer leads 122 of metal circuit 120 are used to be output ends of the optical device 100, then no need for surface mounting. By the way the image sensor device like optical device 100 can be installed in a folding portable telephone (as shown in FIG. 3) or other portable electronic product reaching a quick assembling and wide adjustable range. Comparatively, the conventional optical device must execute surface mounting or insert on a printed circuit board first, and using the flexible flat cable to lead the output end out. The optical device 100 obviously avoids a troublesome assembly process and occupies a smaller space.

The tape carrier packaging method of foregoing optical device is described below:

A tape is provided ,being a flexible circuit board, with an upside surface 111, an underside surface 112 and a plurality of windows 113. A plurality of metal circuits 120 are formed on the upside surface 111. Each metal circuit has a inner lead 121 extending to the windows 113.

At least an optical sensor chip 130 is provided with a plurality of electrodes 131 being formed on the sensible surface of each optical sensor chip 130.

Thereafter, the inner leads 121 of metal circuits 120 are bonded by thermal compression with the electrodes 131 of optical sensor chip 130 through the windows 113. Besides, the underside surface 112 of the tape around the window 113 is adhered to the perimeter of the sensible surface of the optical sensor chip 130 by adhesive 132 or tape.

A base 140 is formed, such as molding having a recession 141 used to accommodate optical sensor chip 130. The recession 141 is located under the underside surface 112 of flexible circuit board 110 and is corresponding to the window 113. The base 140 has a surrounding dam 142 (through the opening 114 of flexible circuit board 110). The surrounding dam 142 extends onto the upside surface 111 of flexible circuit board 110.

A transparent cover 150 is fixedly attachedto the surrounding dam 142 of the base 140.

In the second embodiment of the present invention, as shown in FIG. 4 another optical device 200 with a tape carrier package is illustrated. The optical device 200 comprises a flexible circuit board 210, an optical sensor chip 230, a thermosetting filler 240 and a transparent cover 250. The optical sensor chip 230 has a plurality of electrodes 231 formed on the sensible surface. The flexible circuit board 210 has an upside surface 211, an underside surface 212 and a window 213. A plurality of metal circuits 220 are formed on the upside surface 211. Each metal circuit 220 has an inner leads 221 extending to the window 213 such that it electrically connects the electrodes 231 of optical sensor chip 230 and an outer lead 222. Preferably, all outer leads 222 extend to a same side. Besides, the optical device 200 further comprises adhesive compound 232, 251 like thermal melting compound or adhesive tape, wherein the adhesive compound 232 is used to adhere the underside surface 212 of flexible circuit board 210 and the optical sensor chip 230, and the adhesive compound 251 is used to adhere the upside surface 211 of flexible circuit board 210 and the transparent cover 250 for providing necessary adhesion in the manufacturing process. Thereafter a liquid thermosetting filler 240 is formed around the perimeter of the chip 230 by the potting technique. During potting, the liquid thermosetting filler 240 is blocked around the sensible surface of the optical sensor chip 230 and flows through the opening of flexible circuit board 210 to the surrounding gap between transparent cover 250 and flexible circuit board 210, then being baked and cured. The thermosetting filler 240effectively bonds the transparent cover 250 and the flexible circuit board 210 for sealing the optical sensor chip 230 in the window 213, so that the optical device 200 not only can be packaged at lower cost but also has a better stability and sealing due to a stable bonding strength between optical sensor chip 230 and flexible circuit board 210 by means of adhesive compound 232, 251 and thermosetting filler 240.

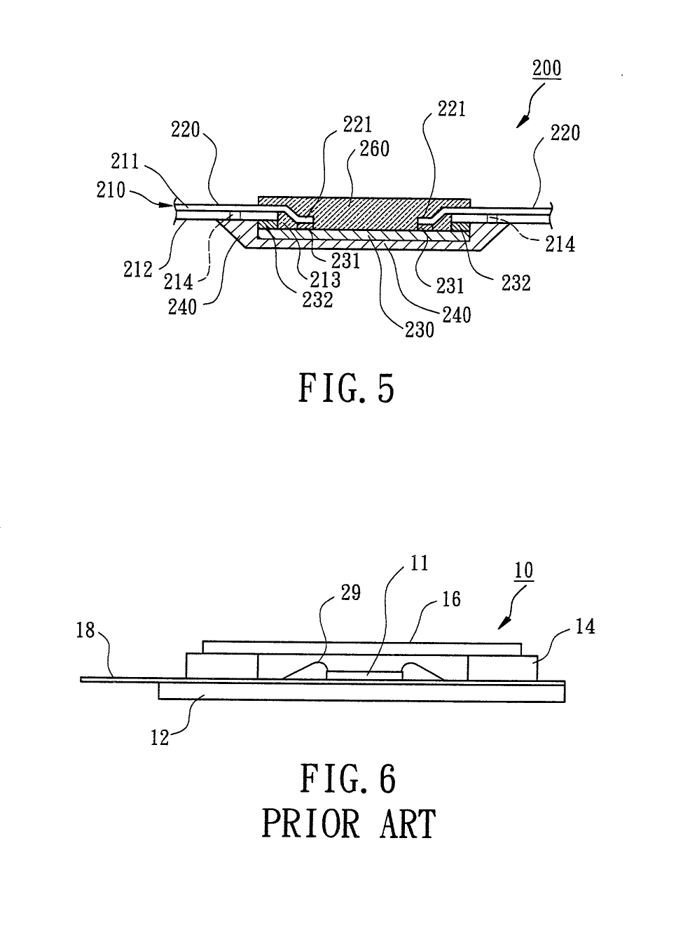

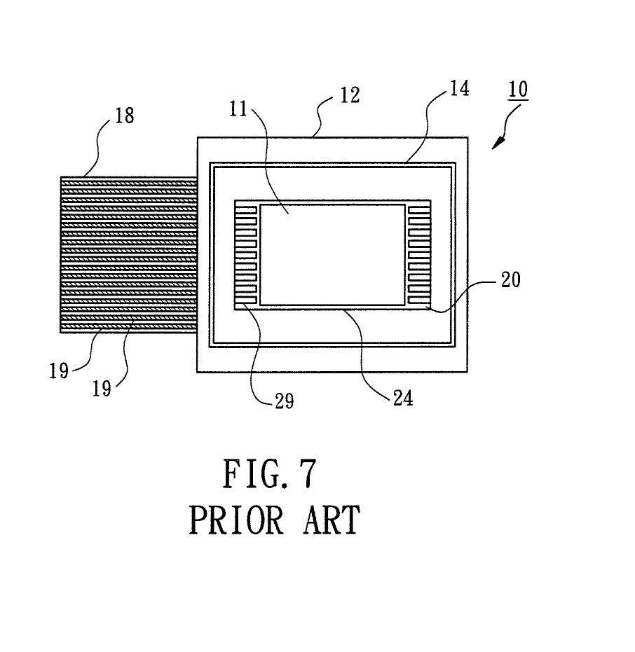

In the third embodiment of the present invention, as shown in FIG. 5, an optical device with a tape carrier package is illustrated, wherein if the elements as same as used in the second embodiment their elements number will still be used in this embodiment. The optical device comprises a flexible circuit board 210, an optical sensor chip 230, a thermosetting filler 240 and a transparent gel 260. A plurality of electrodes 231 are formed on the sensible surface of optical sensor chip 230. The flexible circuit board 210 has an upside surface 211, an underside surface 212 and a window 213. A plurality of metal circuits 220 are formed on the upside surface 211 and have their inner leads 221 extending to the window 213 for bonding the electrodes 231 of optical sensor chip 230and their outwardly-extending outer leads 222. Besides, the optical device 200 further comprises an adhesive compound 232 such as thermal melting compound or adhesive tape around the window 232.The adhesive compound 232 bonds by adhering the underside surface 212 of flexible circuit board 210 and the optical sensor chip 230 for blocking the thermosetting filler 240 flowing into the sensible surface of optical sensor chip 230. After thermal compression, the thermosetting filler 240 is formed on the underside surface 212 of flexible circuit board 210 in the first molding process and covers the backside of optical sensor chip 230 to form a carrying base. The transparent gel 260 is a thermosetting silicon gel of high transparency, by the second molding process being formed on the sensible surface of optical sensor chip 230. Therefore, the optical device has lower cost packaging, better stability and sealing for the optical sensor chip.

The above description of embodiments of this invention is intended to be illustrative and not limiting. Other embodiments of this invention will be obvious to those skilled in the art in view of the above disclosure.

What is claimed is:

1. An optical device with a tape carrier package comprising:
an optical sensor chip forming a plurality of electrodes on its sensible surface;
a flexible circuit board having an upside surface, an underside surface and a window, wherein the underside surface around the window is adhered to the perimeter of the sensible surface of the optical sensor chip;
a plurality of metal circuits formed on the flexible circuit board and having inner leads extending to the window for bonding with the corresponding electrodes of the optical sensor chip and outer leads; and
a base having a recession to accommodate the optical sensor chip being located under the underside surface of the flexible circuit board and being corresponding to the window.

2. The optical device with a tape carrier package of claim 1, wherein the base has a surrounding dam which extends onto the upside surface of the flexible circuit board.

3. The optical device with a tape carrier package of claim 2, further comprising a transparent cover fixedly attached to the surrounding dam of the base.

4. The optical device with a tape carrier package of claim 1, wherein the flexible circuit board further forms a plurality of openings around the window.

5. The optical device with a tape carrier package of claim 1, wherein the outer leads of the metal circuits extends in a same direction.

6. An optical device with a tape package comprising:
an optical sensor chip forming a plurality of electrodes on its sensible surface;
a flexible circuit board having an upside surface, an underside surface and a window,
wherein the underside surface around the window is adhered to the perimeter of the sensible surface of the optical sensor chip;
a plurality of metal circuits formed on the flexible circuit board and having inner leads extending to the window for bonding with the corresponding electrodes of the optical sensor chip and outer leads; and
a thermosetting filler at least formed at the connection perimeter of the optical sensor chip and the underside surface of the flexible circuit board.

7. The optical device with a tape carrier package of claim 6, further comprising a transparent cover on the upside surface of the flexible circuit board.

8. The optical device with a tape carrier package of claim 6, further comprising a transparent gel filling on the sensible surface of the optical sensor chip.

9. The optical device with a tape carrier package of claim 6, wherein the flexible circuit board further forms a plurality of openings around the window.

10. The optical device with a tape carrier package of claim 9, wherein the thermosetting filler is partially formed on the upside surface of the flexible circuit board through the openings.

11. The optical device with a tape carrier package of claim 6, wherein the outer leads of the metal circuits extends in a same direction.

12. The optical device with a tape carrier package of claim 6, wherein the thermosetting filler is a base for carrying the optical sensor chip.

13. A tape carrier packaging method for the optical device comprising:
providing a tape having an upside surface, an underside surface and a plurality of windows, wherein a plurality of metal circuits are formed on the upside surface and have the inner leads extending to the windows;
providing at least an optical sensor chip having a plurality of electrodes being formed on the sensible surface of each optical sensor chip;
thermal compressing the inner leads of the metal circuits in the window for bonding with the electrodes of the optical sensor chip; and
forming a thermosetting filler to seal the connection perimeter of the optical sensor chip and the flexible circuit board.

14. The tape carrier packaging method for the optical device of claim 13, wherein in the step of forming a thermosetting filler, by molding and injection the formed base has a recession accommodating the optical sensor chip, located under the underside surface of the flexible circuit board and being corresponding to the window, and a surrounding dam which extends onto the upside surface of the tape.

15. The tape carrier packaging method for the optical device of claim 14, further comprising a step:
fixedly attaching a transparent cover to the surrounding dam of the base.

16. The tape carrier packaging method for the optical device of claim 13, wherein a plurality of openings are formed around each window.
